(19) United States
(12) Patent Application Publication
(10) Pub. No.: US 2026/0233616 A1
(43) Pub. Date: Aug. 13, 2026

(54) POWER SUPPLY DEVICE

(71) Applicant: TOYOTA JIDOSHA KABUSHIKI KAISHA, Toyota-shi (JP)

(72) Inventor: Soichiro ITO, Toyota-shi (JP)

(73) Assignee: TOYOTA JIDOSHA KABUSHIKI KAISHA, Toyota-shi, (JP)

(21) Appl. No.: 19/427,409

(22) Filed: Dec. 19, 2025

(30) Foreign Application Priority Data
Jan. 20, 2025 (JP) 2025-007972

(51) Int. Cl. B60L 3/00; B60L 3/12; B60L 50/60; B60L 58/20; G01R 19/165; H01H 47/00; H02M 1/00; H02M 3/335; B60L 58/19

(52) U.S. Cl. CPC B60L 3/0069; B60L 3/12; B60L 50/60; B60L 58/20; G01R 19/16542; H01H 47/005; H02M 1/0009; H02M 3/33584; B60L 58/19; B60L 2210/10

(57) ABSTRACT

A power supply device includes a power supply, a first inverter, a second inverter, a first relay, a second relay, a bidirectional DC/DC converter, a capacitor, a voltage detection unit, a control unit, and a determination unit. The bidirectional DC/DC converter includes a pair of first input/output terminals, and a pair of second input/output terminals.

### CROSS-REFERENCE TO RELATED APPLICATION

This application is based upon and claims the benefit of priority of the prior Japanese Patent Application No. 2025-007972, filed on January 20, 2025, the entire contents of which are incorporated herein by reference.

### TECHNICAL FIELD

The present disclosure relates to a power supply device.

### BACKGROUND

As for a power supply device, for example, Japanese Patent Application Publication No. 2020-96520 describes two inverters connected to each other via a winding of each phase of a motor mounted on a vehicle. A relay (SMR: System Main Relay) is provided on each of a pair of power lines connecting the two inverters and a power supply of the motor. When the operation of the motor is finished, each relay is controlled to be opened so as to interrupt the current flow between the power supply and the motor from the viewpoint of ensuring safety.

The relay might be maintained in a closed state due to welding, and might not be able to interrupt the current flow between the power supply and the motor. Therefore, after the opening control of each relay, the inverter operates so that, for example, a smoothing capacitor connected between input terminals of the inverter is discharged, and the welding of the relay is determined according to the voltage of the smoothing capacitor after the discharge.

In addition, with the advancement of functionality of vehicles, after the operation of the motor is finished, for example, in order to secure power for a monitoring camera of a parked vehicle, an auxiliary battery of the vehicle may be charged from a power supply of the motor. In this case, the relay of one power line is controlled to be opened, while the relay of the other power line is maintained in a closed state, and the power source and the auxiliary battery are energized via the relay in the closed state.

On the other hand, the power supply and the inverter are not electrically connected to each other by the relay in the open state. Therefore, even if the other relay is controlled to be opened after the charging of the auxiliary battery is completed, the welding of the relay might not be determined based on the voltage of the smoothing capacitor as described above.

### SUMMARY

It is therefore an object of the present disclosure to provide a power supply device capable of detecting welding of a relay even when a current flow between a power supply and an inverter is interrupted.

The above object is achieved by a power supply device including: a power supply that supplies power to a motor that drives a vehicle; a first inverter and a second inverter connected to each other via a winding of each phase of the motor; a first relay and a second relay connected between both terminals of the power supply and a pair of input terminals of the first inverter and the second inverter, respectively; a bidirectional DC/DC converter including: a pair of first input/output terminals connected to the both terminals of the power supply; and a pair of second input/output terminals connected to both terminals of an auxiliary battery of the vehicle; a capacitor connected between the pair of first input/output terminals; a voltage detection unit configured to detect a voltage between both terminals of the capacitor; a control unit configured to control the first relay, the second relay, and the bidirectional DC/DC converter; and a determination unit configured to determine welding of the second relay, wherein one of the pair of first input/output terminals is connected between one of the both terminals of the power supply and the first relay, another of the pair of first input/output terminals is connected between the second relay and one of the pair of input terminals, the control unit is configured to control the bidirectional DC/DC converter to charge the capacitor and the auxiliary battery from the power supply, when the first relay is in an open state and the second relay is in a closed state, and to control the second relay to be opened and the bidirectional DC/DC converter to discharge the capacitor, after the capacitor and the auxiliary battery are charged, and the determination unit is configured to determine whether the second relay is welded according to the voltage between the both terminals of the capacitor detected by the voltage detection unit, after the bidirectional DC/DC converter is controlled such that the capacitor is discharged.

In the power supply device described above, the determination unit may be configured to determine that the second relay is not welded when an amount of change in the voltage between the both terminals of the capacitor after charging of the capacitor by the bidirectional DC/DC converter is equal to or greater than a threshold value, and the determination unit may be configured to determine that the second relay is welded when the amount of change is less than the threshold value.

The power supply device described above may further include a current detection unit configured to detect a current flow between the bidirectional DC/DC converter and the capacitor, wherein, in a case where the amount of change is less than threshold value, the determination unit may be configured to determine that the second relay is welded when the current detected by the current detection unit is equal to or greater than a predetermined value, and the determination unit may be configured to determine that the second relay is not welded when the current detected by the current detection unit is less than the predetermined value.

The power supply device described above may further include a resistance element connected in parallel to the capacitor, wherein, in a case where the amount of change is less than threshold value, the determination unit may be configured to determine that the second relay is welded, when another amount of change in the voltage between the both terminals of the capacitor during a required period for discharging of the capacitor through a current flow between the capacitor and the resistance element elapses after charging of the capacitor by the bidirectional DC/DC convertor is equal to or greater than the threshold value.

The power supply device described above may further include a third relay connected between another terminal of the power supply and the one of the pair of input terminals, wherein the power supply may include: a fourth relay; and a first battery and a second battery connected in series to each other via the fourth relay, when the determination unit determines welding of the second relay, the third relay may be in an open state and the fourth relay may be in a closed state, the control unit may be configured to control the third relay to close and to control the fourth relay to open, after the determination unit determines that the second relay is welded, and the determination unit may be configured to determine welding of the fourth relay according to the voltage between the both terminals of the capacitor detected by the voltage detection unit, after the third relay is controlled to be closed and the fourth relay is controlled to be opened.

### BRIEF DESCRIPTION OF THE DRAWINGS

FIG. 1 is a configuration view illustrating a power supply device;

FIG. 2A is a configuration view illustrating an ECU (Electronic Control Unit), and FIG. 2B is a circuit diagram illustrating a bidirectional DC/DC converter;

FIG. 3A is a view illustrating a charging operation of the bidirectional DC/DC converter, FIG. 3B is a view illustrating a discharging operation of the bidirectional DC/DC converter, FIG. 3C is a view illustrating a change in voltage from charging to discharging of a capacitor when a relay is not welded, and FIG. 3D is a view illustrating a change in voltage from charging to discharging of the capacitor when the relay is welded;

FIG. 4 is a flowchart illustrating a relay diagnosis operation;

FIG. 5A is a view illustrating a charging unit in another embodiment, and FIG. 5B is a flowchart illustrating a relay diagnosing operation in the other embodiment;

FIG. 6A is a view illustrating a charging unit in still another embodiment, and FIG. 6B is a flowchart illustrating a relay diagnosing operation in the still other.

### DETAILED DESCRIPTION

### Configuration of Power Supply Device

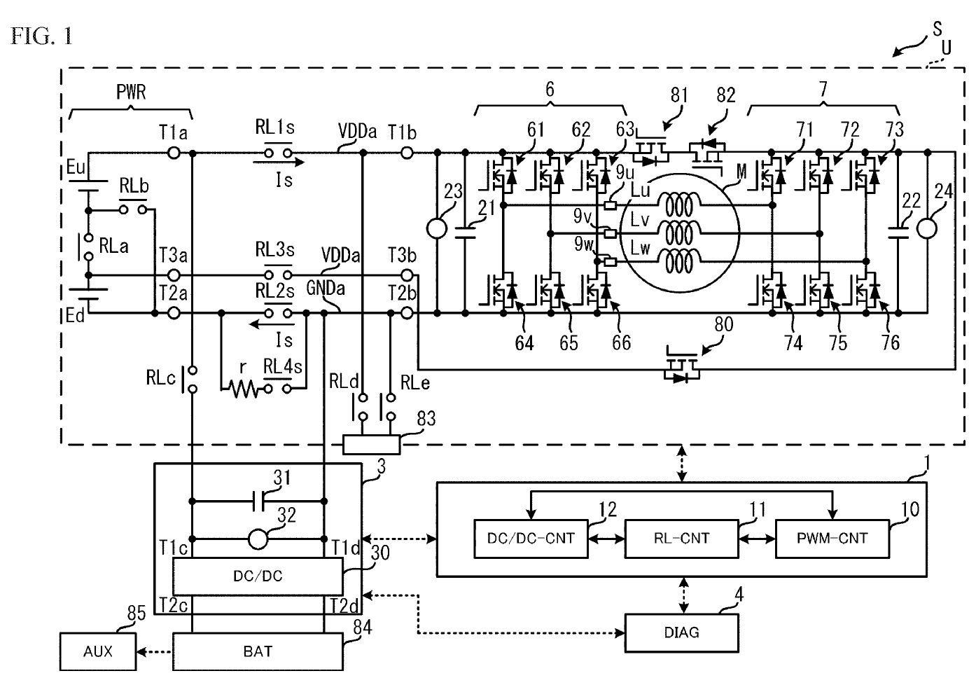

FIG. 1 is a configuration view illustrating a power supply device S. The power supply device S is mounted on a vehicle such as an electric vehicle or a hybrid vehicle. The power supply device S includes a drive unit U, a control unit 1, a charging unit 3, and a diagnosis unit 4.

The drive unit U drives a motor M of a drive source of the vehicle by power supplied from a power supply PWR. The drive unit U includes the power source PWR, the motor M, inverters 6 and 7, current sensors 9u to 9w, smoothing capacitors 21 and 22, a voltage sensors 23 and 24, relays RL1s to RL4s and 80 to 82, and an inlet 83.

The inverters 6 and 7 are examples of first and second inverters. The inverters 6 and 7 are connected to each other via windings Lu, Lv, and Lw of a u phase, a v phase, and a w phase of the motor M, respectively. The power supply PWR supplies power to the motor M. The inverters 6 and 7 convert the output current of the power supply PWR from a direct current to a three phase alternating current and output the current to the motor M. Although not illustrated, the motor M includes, for example, a rotor having a permanent magnet and a stator that generates a magnetic field by a three phase alternating current. The motor M drives the vehicle.

The power supply PWR includes batteries Eu and Ed such as lithium ion batteries, and relays RLa and RLb. The batteries Eu and Ed are connected in series with each other via the relay RLa. The positive pole of the battery Eu is connected to a terminal T1a, and the negative pole of the battery Ed is connected to a terminal T2a. The terminal T3a are connected between an end of the relay RLa and the positive pole of the battery Ed.

An end of the relay RLb is connected between the relay RLa and the battery Eu, and an end of the relay RLb is connected between the negative pole of the battery Ed and the terminal T2a. When the relay RLa is closed and the relay RLb is open, the negative pole of the battery Eu and the positive pole of the battery Ed are directly connected to each other. In this case, the power of the batteries Eu and Ed is supplied from the terminal T1a and T2a to the motor M via power line VDDa and a ground line GNDa. The batteries Eu and Ed are examples of first and second batteries, and the relay RLa is an example of a fourth relay.

The inverter 6 includes switching elements 61 to 66, and the inverter 7 includes switching elements 71 to 76. A freewheeling diode is connected between two input/output terminals of each of the switching elements 61 to 66 and 71 to 76. Examples of the switching elements 61 to 66 and 71 to 76 are, but are not limited to, insulated gate bipolar transistors (IGBT) or metal-oxide-semiconductor field-effect-transistors (MOSFET).

In the inverter 6, the input/output terminal of each of the switching elements 61 to 63 on the upper arm side is connected to the power supply line VDDa, and the input/output terminal of each of the switching elements 64 to 66 on the lower arm side is connected to the ground line GNDa. The switching elements 61 to 63 on the upper arm side and the switching elements 64 to 66 on the lower arm side are directly connected to each other at the other input/output terminals. The connection points, as output terminals, are connected to ends of the windings Lu, Lv, and Lw.

In the inverter 7, the input/output terminal of each of the switching elements 71 to 73 on the upper arm side is connected to the power supply line VDDa, and the input/output terminal of each of the switching elements 74 to 76 on the lower arm side is connected to the ground line GNDa. The switching elements 71 to 73 on the upper arm side and the switching elements 74 to 76 on the lower arm side are directly connected to each other at the other input/output terminals. The connection points, as output terminals, are connected to the other ends of the windings Lu, Lv, and Lw. Further, the control terminals of the switching elements 61 to 66 and 71 to 76 are connected to the control unit 1.

The output terminals of the switching elements 61, 64, 71, and 74 are connected to the winding Lu of the u phase. The output terminals of the switching elements 62, 65, 72, and 75 are connected to the v phase winding Lv. The output terminals of the switching elements 63, 66, 73, and 76 are connected to the w phase winding Lw. The current sensors 9u, 9v, and 9w are connected in series to the windings Lu, Lv, and Lw, respectively. The current sensors 9u, 9v, and 9w detect the current values of the u phase, the v phase, and the w phase, respectively.

The smoothing capacitor 21 is connected between the power supply line VDDa and the ground line GNDa on the input side of the inverter 6. The smoothing capacitor 21 smooths, for example, an input voltage of the inverter 6. The voltage sensor 23 is connected in parallel to the smoothing capacitor 21 and detects a voltage VH between the both terminals of the smoothing capacitor 21.

The smoothing capacitor 22 is connected between the power supply line VDDa and the ground line GNDa on the input side of the inverter 7. The smoothing capacitor 22 smooths, for example, an input voltage of the inverter 7. The voltage sensor 24 is connected in parallel to the smoothing capacitor 22 and detects a voltage VH between the both terminals of the smoothing capacitor 22.

The relays 81 and 82 are provided on the power supply line VDDa between the inverters 6 and 7. The relay 80 is provided on the power supply line VDDa between the inverter 7 and the power supply PWR. When the motor M is driven by the power of the batteries Eu and Ed, the relays 81 and 82 are closed and the relay 80 is opened.

The inverters 6 and 7 includes input terminals T1b to T3b. The terminals T1b and T2b are provided on the power line VDDa and the ground line GNDa, respectively, on the power PWR side of the smoothing capacitor 21, and the terminal T3b is provided on the power line VDDa on the power PWR side of the smoothing capacitor 22. The input terminals T1b and T2b are an example of a pair of input terminals of the first and second inverters.

The relays RL1s to RL4s are connected between the power source PWR and the inverters 6 and 7. The connection form between the power source PWR and the inverters 6 and 7 is switched depending on open/close states of the relays RL1s to RL4s.

The relay RL1s is an example of a first relay, and the relay RL2s is an example of a second relay. The relay RL1s is interposed in the power line VDDa between the terminal T1a of the power source PWR and the input terminal T1b of the inverters 6 and 7. The relay RL2s is interposed in the ground line GNDa between the terminal T2a of the power source PWR and the input terminal T2b of the inverters 6 and 7. The relay RL3s is interposed in the power line VDDa between the terminal T3a of the power source PWR and the input terminal T3b of the inverters 7.

The relay RL4s is connected in series with a resistance r. The ends of the relay RL4s and the resistance r are connected to the ends of the relay RL2s. The relay RL4s is an example of a third relay. The relay RL4s is connected between the terminal T2a of the power source PWR and the input terminal T2b of the inverters 6 and 7. The relay RL4s is closed when the smoothing capacitors 21 and 22 are pre-charged from the power source PWR in a case where the relay RL2s is opened and closed. At this time, the resistor r reduces the rush current from the power supply PWR.

In the power supply PWR, when the relay RLa is in a closed state and the relay RLb is in an open state, the batteries Eu and Ed are connected in series to each other. At this time, when the relays RL1s and RL2s and the relays 81 and 82 are closed and the relays RL3s and RL4s and the relay 80 are opened, the electric power of the batteries Eu and Ed is supplied from the terminals T1b and T2b to the motor M via the inverters 6 and 7. At this time, the switching elements 61 to 66 of the inverter 6 are turned on and off in accordance with a PWM (Pulse Width Modulation) signal input to control terminals thereof, and the switching elements 71 to 73 of the inverter 7 are turned on and the switching elements 74 to 75 are turned off.

In the power supply PWR, when the relay RLa is in an open state and the relay RLb is in a closed state, the batteries Eu and Ed are connected in parallel to each other. At this time, the batteries Eu and Ed are charged from, for example, a DC charger (not illustrated) via the inlet 83. The inlet 83 is connected to the power line VDDa between the relay RL1s and the input terminal T1b of the inverter 7 via the relay RLd, and is connected to the power line VDDa between the relay RL2s and the input terminal T2b of the inverter 7 via the relay RLe. When the batteries Eu and Ed are charged by the DC charger, the relays RLd and RLe are closed.

The charging unit 3 charges an auxiliary battery (BAT) 84 with the power supply PWR. The auxiliary battery 84 supplies electric power to an auxiliary device (AUX) 85 of the vehicle. The auxiliary device 85 may be a monitoring camera of the vehicle, but is not limited thereto.

The charging unit 3 includes a bidirectional DC/DC converter 30, a capacitor 31, and a voltage sensor 32. The charging unit 3 is realized by, for example, a 2-in-1 unit. The 2in1 unit includes an on-board charger (OBC) (not illustrated) and the like in addition to the above-described configuration. The OBC includes, for example, a dual active bridge (DAB), and is used when the batteries Eu and Ed are charged by an AC charger.

A pair of input/output terminals T1c and T1d on the primary side of the bidirectional DC/DC converter 30 are connected to the terminal T1a and T2a of the power source PWR, respectively. The input/output terminals T1c is connected to the power line VDDa between the terminal T1a of the power source PWR and the relay RL1s, and the input/output terminal T1d is connected to the ground line GNDa between the relay RL2s and the input/output terminal T2b of the inverters 6 and 7. The relay RLc is connected between the input/output terminal T1c and the terminal T1a of the power source PWR, and is closed when the auxiliary battery 84 is charged. The input/output terminals T1c and T1d are an example of a pair of first input/output terminals.

The pair of input terminals T2c and T2d of the bidirectional DC/DC converter 30 on the secondary side is connected to positive and negative terminals of the auxiliary battery 84. The input terminals T2c and T2d are an example of a pair of second input/output terminals.

The capacitor 31 is connected between the pair of input/output terminals T1c and T1d on the primary side. The capacitor 31 smooths a voltage between the input/output terminals T1c and T1d. The voltage sensor 32 is connected in parallel with the capacitor 31. The voltage sensor 32 detects a voltage between both ends of the capacitor 31. The voltage sensor 32 is an example of a voltage detection unit.

The control unit 1 controls the drive unit U and the charging unit 3. The control unit 1 includes a PWM controller (PWM-CNT) 10, a relay controller (RL-CNT) 11, and a converter controller (DC/DC-CNT) 12. The control unit 1 is an example of a control unit.

The PWM controller 10 controls the switching operation of the inverters 6 and 7 by outputting PWM signals to the inverters 6 and 7. The PWM controller 10 controls the duty ratio of the PWM signal based on the detection values of the current sensors 9u to 9w and the voltage sensors 23 and 24, for example, according to a required value of the torque of the motor M.

The relay controller 11 controls opening and closing of the relays RLa to RLe, RL1s to RL4s, and 80 to 82. The converter controller 12 controls the operation of the bidirectional DC/DC converter 30. The PWM controller 10, the relay controller 11, and the converter controller 12 operate in cooperation with each other according to an operation state of the vehicle.

The diagnosis unit 4 (DIAG) diagnoses the states of the relays RL2s and RLa. The diagnosis unit 4 (DIAG) cooperates with the control unit 1 to determine welding of the relays RL2s and RLa based on the detection value of the voltage sensor 32 after the auxiliary battery 84 is charged. The diagnosis unit 4 is an example of a determination unit. The diagnosis unit 4, the PWM controller 10, the relay controller 11, and the converter controller 12 are each realized by, for example, an ECU.

### Configuration of ECU

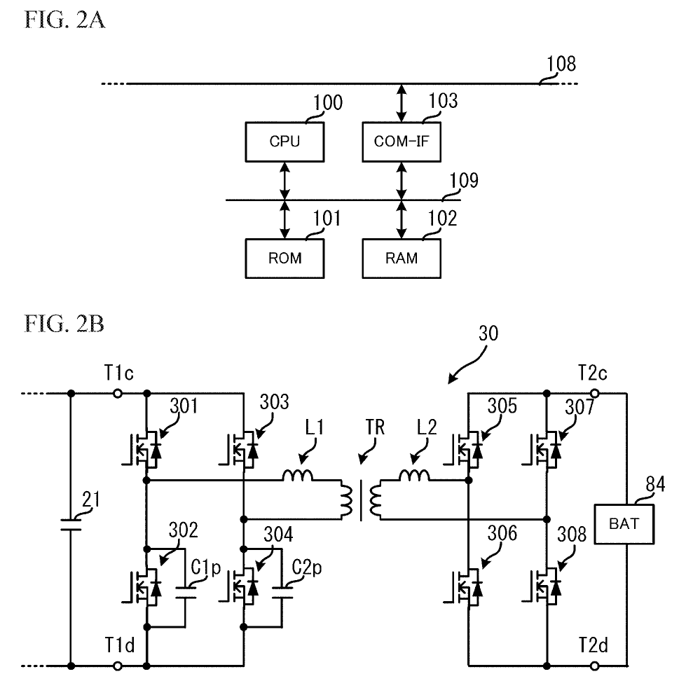

FIG. 2A is a configuration view illustrating the ECU. The ECU is an example of a computer. The ECU includes a central processing unit (CPU) 100, a read only memory (ROM) 101, a random access memory (RAM) 102, a communication interface (COM-IF) 103, and the like. The CPU 100 operates according to a program stored in the ROM 101. The CPU 100 is electrically connected to the ROM 101, the RAM 102, and the COM-IF 103 via a bus 109.

The ROM 101 stores a program for driving the CPU 100. The RAM 102 functions as a working memory for the CPU 100. The COM-IF 103 processes communication between the CPU 100 and another ECU connected via a global bus 108.

The diagnosis unit 4, the PWM controller 10, the relay controller 11, and the converter controller 12 can be realized by a plurality of ECUs connected to each other via the global bus 108, but are not limited thereto, and may be realized by, for example, one or more integrated circuit (IC) chips.

### Configuration of Bidirectional DC/DC Converter

FIG. 2B is a circuit diagram illustrating the bidirectional DC/DC converter 30.

The primary circuit of the bidirectional DC/DC converter 30 includes switching elements 301 to 304 and an inductor L1. The switching elements 305 to 308 and the inductor L2 are provided in the secondary side circuit of the bidirectional DC/DC converter 30. Examples of the switching elements 301 to 308 are, but not limited to, IGBTs or MOSFETs. Input/output terminals of the switching elements 301, 303, 305, and 307 on the upper arm side are connected to input/output terminals of the switching elements 302, 304, 306, and 308 on the lower arm side, respectively.

A transformer TR is connected between the primary side circuit and the secondary side circuit of the bidirectional DC/DC converter 30. The connection points between the switching elements 301, 303, 305, and 307 on the upper arm side and the switching elements 302, 304, 306, and 308 on the lower arm side are connected to the transformer TR. An inductor L1 is connected between the connection point of the switching elements 301 and 302 and the transformer TR. An inductor L2 is connected between the connection point of the switching elements 305 and 306 and the transformer TR.

The other input/output terminals of the switching elements 301 and 303 are connected to the input/output terminal T1c of the bidirectional DC/DC converter 30, and the other input/output terminals of the switching elements 302 and 304 are connected to the input/output terminal T1d of the bidirectional DC/DC converter 30. Bypass capacitors C1p and C2p are connected between the input/output terminals of the switching elements 302 and 304, respectively. The other input/output terminals of the switching elements 305 and 307 are connected to the input/output terminal T2c of the bidirectional DC/DC converter 30, and the other input/output terminals of the switching elements 306 and 308 are connected to the input/output terminal T2d of the bidirectional DC/DC converter 30.

A PWM signal is input from the converter controller 12 to control terminals of the switching elements 301 to 308. As a result, the switching elements 301 to 308 perform on/off operations, and thus voltage conversion is performed between the primary side circuit and the secondary side circuit of the bidirectional DC/DC converter 30. At this time, the smoothing capacitor 21 is charged to be in a pre-charged state, and smooths the voltage between the input/output terminals T1c and T1d.

The bidirectional DC/DC converter 30 charges the auxiliary battery 84 from the power supply PWR while the motor M is stopped. This enables the auxiliary device 85 to operate even when the vehicle is parked.

### Charging Operation

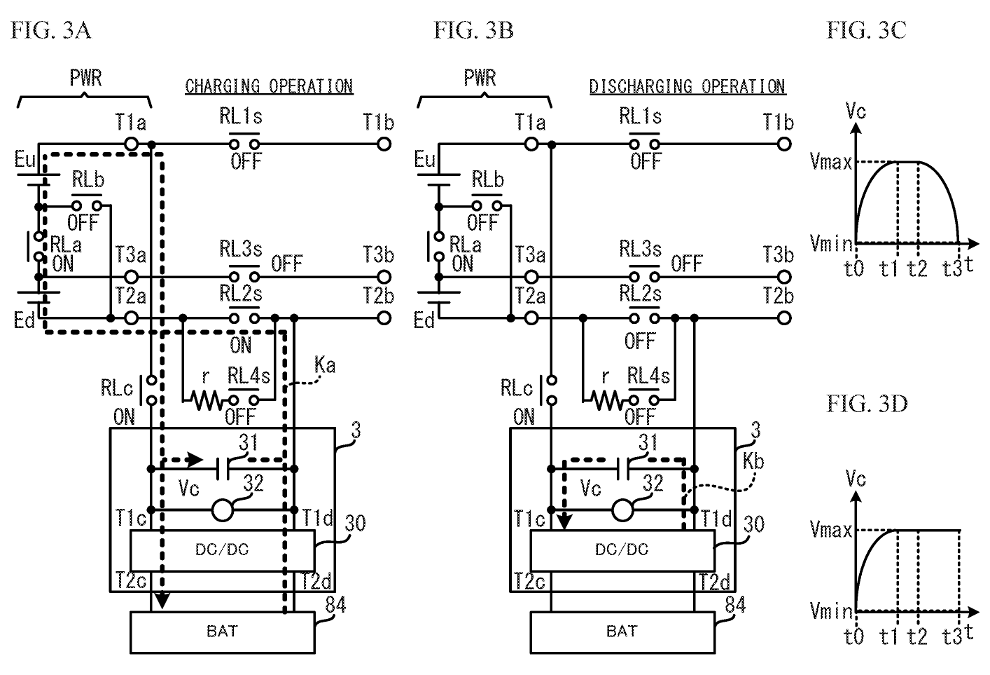

FIG. 3A is a view illustrating a charging operation of the bidirectional DC/DC converter 30. In FIG. 3A, the same symbols are given to the same components as those in FIG. 1, and the description thereof is omitted. FIG. 3A illustrates the power source PWR, the relays RL1s to RL4s, the input terminals T1b to T3b of the inverters 6 and 7, the charging unit 3, and the auxiliary battery 84 in the circuit illustrated in FIG. 1.

Before the charging operation is performed, the relay controller 11 controls the relays RLa to RLe, RL1s to RL4s, and 80 to 82 as follows during the operation of the motor M, that is, during the traveling of the vehicle.

Relays RL1s, RL2s, RLa, RLc, 81, and 82: closed (ON)

Relays RL3s, RL4s, RLb, RLd, RLe, and 80: open (OFF)

The converter controller 12 controls the bidirectional DC/DC converter 30 to perform a step-down operation, for example, while the vehicle is parked, thereby charging the auxiliary battery 84 and the capacitor 31. When the auxiliary battery 84 and the capacitor 31 are charged, the relay controller 11 controls the relays RLa to RLe, RL1s to RL4s, and 80 to 81 as follows.

Relays RL2s, RLa, and RLc: closed

Relays RL1s, RL3s, RL4s, RLb, RLd, RLe, and 80 to 81: open

Here, the relay controller 11 controls the relay RL1s to open so as to cut off the conduction between the terminal T1a of the power source PWR and the input terminal T1b of the inverters 6 and 7 from the viewpoint of ensuring safety. The relay RL2s is kept in a closed state to electrically connect the power source PWR to the charging unit 3 and the auxiliary battery 84.

By the above control, the power supply PWR is connected to the auxiliary battery 84 via the charging unit 3. Therefore, a current flows from the batteries Eu and Ed of the power supply PWR to the auxiliary battery 84 and the capacitor 31 along a path Ka. At this time, since the power supply PWR and the capacitor 31 are connected in parallel, the voltage Vc after the capacitor 31 is charged is substantially the same as the total voltage of the batteries Eu and Ed. Since the auxiliary battery 84 is charged in this manner, the electric power of the auxiliary device 85 is secured even during parking.

After the auxiliary battery 84 is charged, the relay controller 11 controls the relay RL2s to be opened from the viewpoint of ensuring safety. However, since the power between the power source PWR and the inverters 6 and 7 has already been cut off, the diagnosis unit 4 cannot use the method of determining the welding of the relay RL2s based on the voltage change at the time of the discharge of the smoothing capacitor 21 on the inputs side of the inverters 6 and 7. Therefore, as described below, welding of the relay RL2s is determined based on a voltage change at the time of discharging of the capacitor 31 of the charging unit 3.

### Discharging Operation

FIG. 3B is a view illustrating a discharging operation of the bidirectional DC/DC converter 30. In FIG. 3B, the same symbols are given to the same components as those in FIG. 1, and the description thereof is omitted. FIG. 3B illustrates the power source PWR, the relays RL1s to RL4s, the input terminals T1b to T3b of the inverters 6 and 7, the charging unit 3, and the auxiliary battery 84 in the circuit illustrated in FIG. 1.

After the capacitor 31 and the auxiliary battery 84 are charged, the relay controller 11 controls the relays RLa to RLe, RL1s to RL4s, and 80 to 81 as follows.

Relays RLa and RLc: closed (ON)

Relays RL1s to RL4s, RLb, RLd, RLe, and 80 to 81: open (OFF)

Here, the relay controller 11 controls the relay RL2s to open so as to cut off the conduction between the terminal T2a of the power source PWR and the input terminal T2b of the inverters 6 and 7, but the relay RL2s might be maintained in a closed state by welding. The converter controller 12 controls the bidirectional DC/DC converter 30 to perform a boosting operation, thereby performing the discharging operation of the capacitor 31. Accordingly, a current flows between the capacitor 31 and the bidirectional DC/DC converter 30 along a path Kb. At this time, for example, the electric charge of the capacitor 31 is charged to the bypass capacitors C1p and C2p in the bidirectional DC/DC converter 30.

After the bidirectional DC/DC converter 30 is controlled so that the capacitor 31 is discharged, the diagnosis unit 4 determines welding of the relay RL2s according to the voltage Vc between the both terminals of the capacitor 31 detected by the voltage sensor 32. When the relay RL2s is kept in the closed state by welding, the total voltage of the batteries Eu and Ed is applied to the both terminals of the capacitor 31 because the power source PWR and the capacitor 31 are connected in parallel. In this case, even if the bidirectional DC/DC converter 30 operates, the capacitor 31 cannot be discharged because a voltage is applied from the power supply PWR to the capacitor 31. Therefore, the voltage Vc between the both terminals of the capacitor 31 does not substantially decrease from the value at the time of charging.

On the other hand, when the relay RL2s is not welded and is in an open state, the current flow between the power source PWR and the capacitor 31 is cut off, and thus the capacitor 31 can be discharged according to the operation of the bidirectional DC/DC converter 30. Therefore, the voltage Vc between the both terminals of the capacitor 31 decreases with the discharge.

FIG. 3C is a view illustrating a change in the voltage Vc from the charging to the discharging of the capacitor 31 when the relay RL2s is not welded. The horizontal axis represents time t, and the vertical axis represents the voltage Vc between the both terminals of the capacitor 31.

The capacitor 31 is charged in the period from the time t0 to the time t1, and is discharged in the subsequent period from the time t2 to the time t3. At time t0, for example, the voltage Vc of the capacitor 31 is Vmin (≈0V). At time t1, for example, the voltage Vc of the capacitor 31 is Vmax. Vmax is a value close to 2×Vx, for example, where Vx is the voltage of the batteries Eu and Ed after the auxiliary battery 84 is charged. At time t3, for example, the voltage Vc of the capacitor 31 becomes Vmin.

FIG. 3D is a view illustrating a change in the voltage Vc from charging to discharging of the capacitor 31 when the relay RL2s is welded. In the period from time t2 to t3, the capacitor 31 cannot discharge because the relay RL2s remains closed due to welding. Therefore, the voltage Vc of the capacitor 31 remains at Vmax even after the time t2.

The diagnosis unit 4 acquires the voltage Vc of the capacitor 31 from the voltage sensor 32 during charging and after discharging of the capacitor 31. The diagnosis unit 4 diagnoses the state of the relay RL2s based on the amount of change (|Vmax-Vmin|) in the voltage Vc from the time of charging (time t1 to t2) of the capacitor 31 to the time after discharging (from time t3). The diagnosis unit 4 determines that the relay RL2s is not welded when the amount of change in the voltage Vc is equal to or greater than a threshold value TH, and determines that the relay RL2s is welded when the amount of change in the voltage Vc is less than the threshold value TH. Therefore, the diagnosis unit 4 accurately determines the welding of the relay RL2s based on the amount of decrease in the voltage Vc due to the discharge of the capacitor 31.

Alternatively, the diagnosis unit 4 may determine the welding of the relay RL2s with high accuracy based on only the voltage Vc after the discharge of the capacitor 31. In this case, the diagnosis unit 4 compares the voltage Vc after the discharge of the capacitor 31 with a predetermined voltage range according to a previous simulation result or the like, and determines that the relay RL2s is welded when the voltage Vc is out of the predetermined voltage range, and determines that the relay RL2s is not welded when the voltage Vc is within the predetermined voltage range.

The diagnosis unit 4 diagnoses the state of the relay RLa in addition to the relay RL2s. After the determination of the welding of the relay RL2s, the relay controller 11 controls the relay RLa to be opened so as to interrupt the current flow between the batteries Eu and Ed from the viewpoint of ensuring safety. Since the relay RL2s is in the open state, the relay controller 11 closes the relay RL4s so that the power source PWR and the charging unit 3 are connected to each other.

After the relay RL4s is controlled to be closed and the relay RLa is controlled to be opened, the diagnosis unit 4 determines welding of the relay RLa according to the voltage Vc between the both terminals of the capacitor 31 detected by the voltage sensor 32. When the relay RLa is opened, the current flow between the batteries Eu and Ed is cut off. Therefore, when the relay RLa is normally in the open state, the voltages of the batteries Eu and Ed are not applied between the both terminals of the capacitor 31. On the other hand, when the relay RLa is kept in the closed state due to welding, the voltages of the batteries Eu and Ed are applied between the both terminals of the capacitor 31.

Therefore, when the voltage Vc of the capacitor 31 is less than a predetermined value K lower than the voltage of the batteries Eu and Ed, the diagnosis unit 4 determines that the relay RLa is not welded. In this case, the voltage Vc of the capacitor 31 is maintained at, for example, the voltage (Vmin) after the discharge. When the voltage Vc of the capacitor 31 is equal to or higher than the predetermined value K, the diagnosis unit 4 determines that the relay RLa is welded. In this case, the voltage Vc of the capacitor 31 is substantially equal to the voltage (> Vmin) of the batteries Eu and Ed.

As described above, the diagnosis unit 4 detects welding of the relays RL2s and RLa even when the current flow between the power source PWR and the inverters 6 and 7 is interrupted.

### Diagnostic Operation

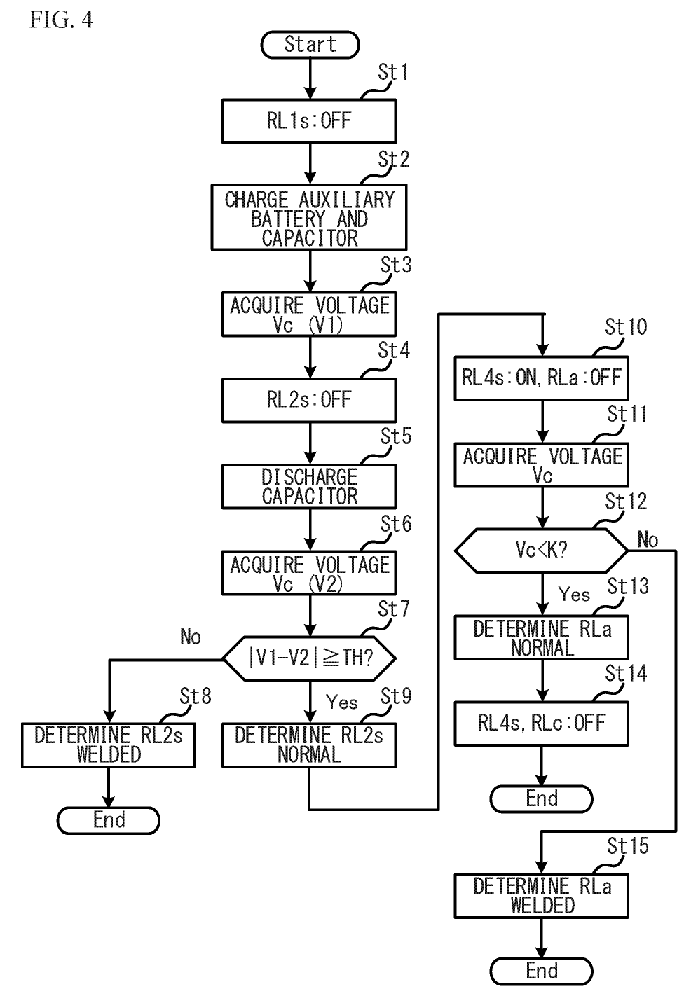

FIG. 4 is a flowchart illustrating a diagnostic operation of the relay RL2s and the relay RLa. This operation is executed, for example, while the vehicle is parked. At the start of this operation, the states of the relays RLa to RLe, RL1s to RL4s, and 80 to 82 are as follows.

Relays RL1s, RL 2s, RLa, and RLc: closed

Relays RL3s, RL4s, RLb, RLd, RLe, and 80 to 82: open

First, the relay controller 11 controls the relay RL1s to open (OFF) (St1). This interrupts the current flow between the power supply PWR and the inverters 6 and 7. Next, the converter controller 12 controls the bidirectional DC/DC converter 30 to charge the auxiliary battery 84 and the capacitor 31 (St2). The converter controller 12 ends the charging operation when the voltage of the auxiliary battery 84 reaches the target value. Next, the diagnosis unit 4 acquires the voltage Vc of the capacitor 31 from the voltage sensor 32 (St3). The voltage Vc at this time is referred to as a V1.

Next, the relay controller 11 controls the relay RL2s to open (OFF) (St4).

Next, the converter controller 12 controls the bidirectional DC/DC converter 30 to discharge the capacitor 31 (St5). Next, the diagnosis unit 4 acquires the voltage Vc of the capacitor 31 from the voltage sensor 32 (St6). The voltage Vc at this time is referred to as a V2.

Next, the diagnosis unit 4 compares the amount of change (|V1 - V2|) from the voltage V1 when the capacitor 31 is charged to the voltage V2 after the capacitor 31 is discharged with the threshold value TH (St7). When the amount of change is less than the threshold value TH (No in St7), the diagnosis unit 4 determines that the relay RL2s is welded (St8). When the amount of change is equal to or greater than the threshold value TH (Yes in St7), the diagnosis unit 4 determines that the relay RL2s is not welded (normal) (St9).

Next, the relay controller 11 controls the relay RL4s to close (ON) and controls the relay RLa to open (OFF) (St10). Next, the diagnosis unit 4 acquires the voltage Vc of the capacitor 31 from the voltage sensor 32 (St11). Next, the diagnosis unit 4 compares the voltage Vc of the capacitor 31 with the predetermined value K (St12). The predetermined value K is set based on the voltage of the batteries Eu and Ed after the capacitor 31 is discharged.

When the voltage Vc is equal to or higher than the predetermined value K (No in St12), the diagnosis unit 4 determines that the relay RLa is welded (St15). When the voltage Vc is less than the predetermined value K (Yes in St12), the diagnosis unit 4 determines that the relay RLa is not welded (normal) (St13).

Next, the relay controller 11 controls the relays RL4s and RLc to open (OFF) (St14). In this way, the diagnostic operation of the relays RL2s and RLa is performed.

### Other Embodiments

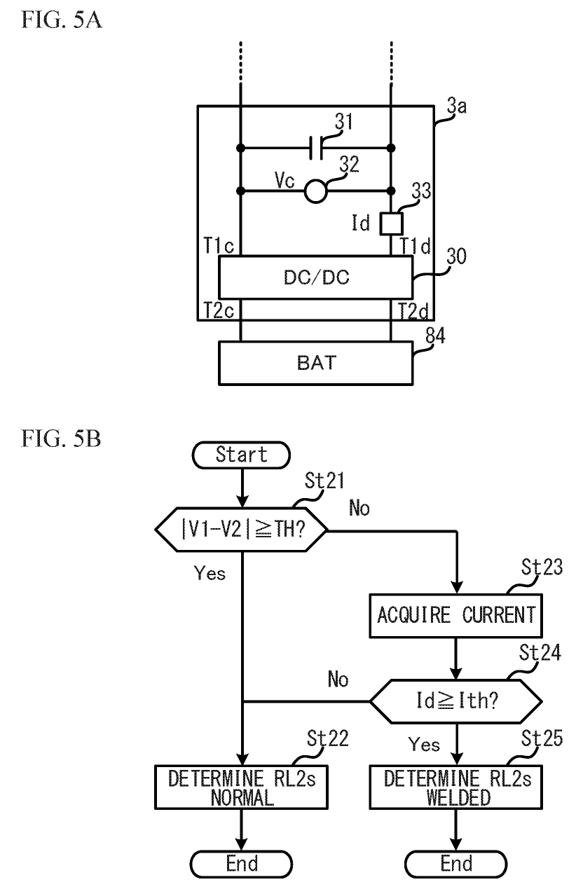

FIG. 5A is a view illustrating a charging unit 3a in another embodiment. In FIG. 5A, the same symbols are given to the same components as those in FIG. 1, and the description thereof is omitted.

The charging unit 3a includes the bidirectional DC/DC converter 30, the capacitor 31, the voltage sensor 32, and a current sensor 33. The current sensor 33 is connected between the input/output terminal T1d of the bidirectional DC/DC converter 30 and an end of the capacitor 31 and the voltage sensor 32. The current sensor 33 detects a current Id flowing between bidirectional DC/DC converter 30 and the capacitor 31. The current sensor 33 is an example of a current detection unit.

The diagnosis unit 4 acquires the current Id from the current sensor 33. When the bidirectional DC/DC converter 30 cannot discharge due to an abnormality, the voltage Vc during the period from charging to discharging of the capacitor 31 does not substantially change even if the relay RL2s is normally opened. In this case, in the above-described diagnostic operation, |V1-V2|<TH is established (No in St7), and it is erroneously determined that the relay RL2s is welded (St8). At this time, no current flows between the capacitor 31 and the bidirectional DC/DC converter 30.

Therefore, the diagnosis unit 4 determines whether or not there is an abnormality in the bidirectional DC/DC converter 30 based on the current Id detected by the current sensor 33. Even when |V1-V2|<TH is satisfied, the diagnosis unit 4 determines that the relay RL2s is not welded when the abnormality of the bidirectional DC/DC converter 30 is determined based on the current Id.

FIG. 5B is a flowchart illustrating the diagnostic operation of the relay RL2s in another embodiment. FIG. 5B illustrates only the operations corresponding to the reference numerals St7 to St9 in FIG. 4.

The diagnosis unit 4 compares the amount of change |V1-V2| from the voltage V1 when the capacitor 31 is charged to the voltage V2 after the capacitor 31 is discharged with the threshold value TH (St21). When the amount of change is equal to or greater than the threshold value TH (Yes in St21), the diagnosis unit 4 determines that the relay RL2s is not welded (normal) (St22).

When the amount of change is less than the threshold value TH (No in St21), the diagnosis unit 4 acquires the current Id from the current sensor 33 (St23). The diagnosis unit 4 then compares the value of the current Id with a threshold value Ith (St24). Here, the threshold value Ith is set to a value close to 0.

When Id≥Ith is satisfied (Yes in St24), the diagnosis unit 4 determines that the bidirectional DC/DC converter 30 is normal, and determines that the relay RL2s is welded (St25). In addition, when Id<Ith is satisfied (No in St24), the diagnosis unit 4 determines that the bidirectional DC/DC converter 30 is abnormal, and determines that the relay RL2s is not welded (normal) (St22). The diagnostic operation is performed in this manner.

As described above, even when the bidirectional DC/DC converter 30 cannot discharge the capacitor 31 due to an abnormality, the diagnosis unit 4 determines welding of the relay RL2s based on the current Id detected by the current sensor 33.

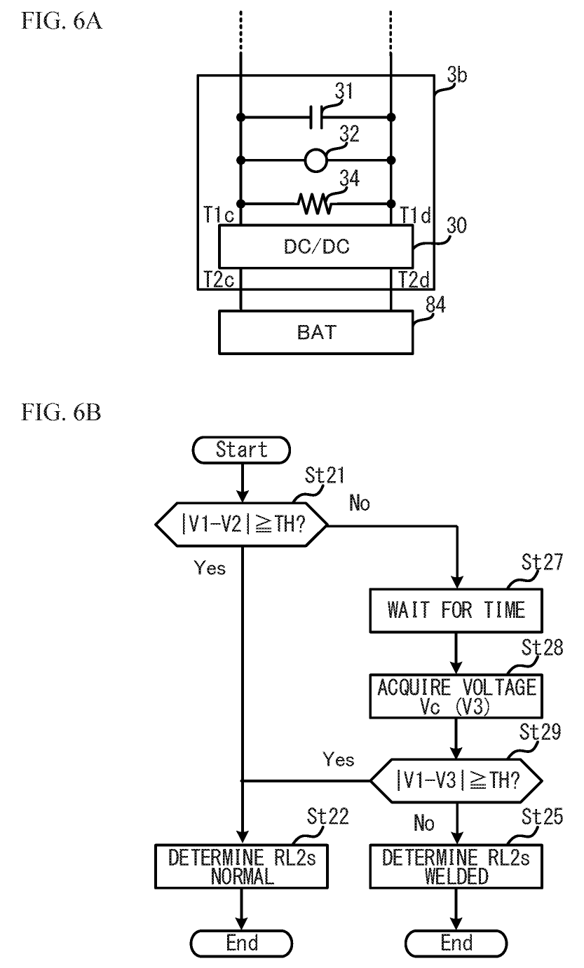

FIG. 6A is a view illustrating a charging unit 3b in still another embodiment.

In FIG. 6A, the same symbols are given to the same components as those in FIG. 1, and the description thereof is omitted.

The charging unit 3b includes the bidirectional DC/DC converter 30, the capacitor 31, the voltage sensor 32, and a resistance element 34. The resistance element 34 is connected in parallel with the capacitor 31 between the input/output terminals T1c and T1d of the bidirectional DC/DC converter 30.

Therefore, when the bidirectional DC/DC converter 30 and the capacitor 31 are disconnected from each other due to an abnormality in the bidirectional DC/DC converter 30, a loop circuit is formed between the resistance element 34 and the capacitor 31. Therefore, even when the capacitor 31 cannot be discharged due to an abnormality of the bidirectional DC/DC converter 30, the capacitor 31 can be discharged via the resistance element 34.

The time required for passive discharge of the capacitor 31 by the resistance element 34 is longer than the time required for active discharge of the capacitor 31 by the bidirectional DC/DC converter 30. The time required for the passive discharge is determined by a time constant based on the resistance value of the resistance element 34 and the capacitance of the capacitor 31. Therefore, in a case where the amount of change in the voltage Vc after the capacitor 31 is discharged is less than the threshold value TH, when the amount of change in the voltage Vc from the time when the capacitor 31 is charged to the time when the required time elapses is equal to or greater than the threshold value TH, the diagnosis unit 4 determines that the relay RL2s is welded. Therefore, even when the bidirectional DC/DC converter 30 cannot discharge due to an abnormality, the diagnosis unit 4 determines welding of the relay RL2s based on the voltage Vc after the capacitor 31 is discharged by the resistance element 34.

FIG. 6B is a flowchart illustrating the diagnostic operation of the relay RL2s in the present embodiment. FIG. 6B illustrates only the operations corresponding to the reference numerals St7 to St9 in FIG. 4. In FIG. 6B, the same symbols are given to the operations common to FIG. 5B, and the description thereof is omitted.

When the amount of change in the voltage Vc of the capacitor 31 is less than the threshold value TH (No in St21), the diagnosis unit 4 waits for a time required for discharging (passive discharging) of the capacitor 31 by the current flow between the capacitor 31 and the resistance element 34 (St27). Next, the diagnosis unit 4 acquires the voltage Vc of the capacitor 31 from the voltage sensor 32 (St28). The voltage Vc at this time is referred to as a V3.

Next, the diagnosis unit 4 compares the amount of change |V1-V3| from the voltage V1 when the capacitor 31 is charged to the voltage V3 after the capacitor 31 is discharged with the threshold value TH (St29). When the amount of change is equal to or greater than the threshold value TH (Yes in St29), the diagnosis unit 4 determines that the relay RL2s is not welded (normal) (St22). When the amount of change is less than the threshold value TH (No in St29), the diagnosis unit 4 determines that the relay RL2s is welded (normal) (St25). The diagnostic operation is performed in this manner.

As described above, even when the bidirectional DC/DC converter 30 cannot discharge the capacitor 31 due to an abnormality, the diagnosis unit 4 determines whether the relay RL2s is welded after the time required for discharging the capacitor 31 by the resistance element 34 has elapsed.

Although some embodiments of the present disclosure have been described in detail, the present disclosure is not limited to the specific embodiments but may be varied or changed within the scope of the present disclosure as claimed.

What is claimed is:

1. A power supply device comprising:
a power supply that supplies power to a motor that drives a vehicle;
a first inverter and a second inverter connected to each other via a winding of each phase of the motor;
a first relay and a second relay connected between both terminals of the power supply and a pair of input terminals of the first inverter and the second inverter, respectively;
a bidirectional DC/DC converter including:
a pair of first input/output terminals connected to the both terminals of the power supply; and
a pair of second input/output terminals connected to both terminals of an auxiliary battery of the vehicle;
a capacitor connected between the pair of first input/output terminals;
a voltage detection unit configured to detect a voltage between both terminals of the capacitor;
a control unit configured to control the first relay, the second relay, and the bidirectional DC/DC converter; and
a determination unit configured to determine welding of the second relay,
wherein
one of the pair of first input/output terminals is connected between one of the both terminals of the power supply and the first relay,
another of the pair of first input/output terminals is connected between the second relay and one of the pair of input terminals,
the control unit is configured to control the bidirectional DC/DC converter to charge the capacitor and the auxiliary battery from the power supply, when the first relay is in an open state and the second relay is in a closed state, and to control the second relay to be opened and the bidirectional DC/DC converter to discharge the capacitor, after the capacitor and the auxiliary battery are charged, and
the determination unit is configured to determine whether the second relay is welded according to the voltage between the both terminals of the capacitor detected by the voltage detection unit, after the bidirectional DC/DC converter is controlled such that the capacitor is discharged.

2. The power supply device according to claim 1, wherein
the determination unit is configured to determine that the second relay is not welded when an amount of change in the voltage between the both terminals of the capacitor after charging of the capacitor by the bidirectional DC/DC converter is equal to or greater than a threshold value, and
the determination unit is configured to determine that the second relay is welded when the amount of change is less than the threshold value.

3. The power supply device according to claim 2, further comprising a current detection unit configured to detect a current flow between the bidirectional DC/DC converter and the capacitor,
wherein, in a case where the amount of change is less than threshold value, the determination unit is configured to determine that the second relay is welded when the current detected by the current detection unit is equal to or greater than a predetermined value, and the determination unit is configured to determine that the second relay is not welded when the current detected by the current detection unit is less than the predetermined value.

4. The power supply device according to claim 2, further comprising a resistance element connected in parallel to the capacitor,
wherein, in a case where the amount of change is less than threshold value, the determination unit is configured to determine that the second relay is welded, when another amount of change in the voltage between the both terminals of the capacitor during a required period for discharging of the capacitor through a current flow between the capacitor and the resistance element elapses after charging of the capacitor by the bidirectional DC/DC convertor is equal to or greater than the threshold value.

5. The power supply device according to claim 1, further comprising a third relay connected between another terminal of the power supply and the one of the pair of input terminals,
wherein
the power supply includes:
a fourth relay; and
a first battery and a second battery connected in series to each other via the fourth relay,
when the determination unit determines welding of the second relay, the third relay is in an open state and the fourth relay is in a closed state,
the control unit is configured to control the third relay to close and to control the fourth relay to open, after the determination unit determines that the second relay is welded, and
the determination unit is configured to determine welding of the fourth relay according to the voltage between the both terminals of the capacitor detected by the voltage detection unit, after the third relay is controlled to be closed and the fourth relay is controlled to be opened.
